(19) United States
(12) Patent Application Publication
(10) Pub. No.: US 2010/0163105 A1
(43) Pub. Date: Jul. 1, 2010

(54) SOLAR CELL PACKAGE TYPE WITH SURFACE MOUNT TECHNOLOGY STRUCTURE

(76) Inventors: YUNG-HUI CHUANG, HSINCHU CITY (TW); HAN-HWA CHOU, HSINCHU CITY (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/644,496

(22) Filed: Dec. 22, 2009

(30) Foreign Application Priority Data
Dec. 31, 2008 (TW) 097223771

(51) Int. Cl. H01L 31/00

(52) U.S. Cl. 136/256

(57) ABSTRACT

A solar cell package type with surface mount technology structure, comprising: a solar cell having a first electric terminal at the bottom thereof and a second electric terminal at the top thereof; at least a connection electric terminal capped at both sides of the solar cell in such a way that the top of the connection electric terminal is connected to the second electric terminal; and at least an insulation layer capped at both sides and partially placed at the bottom of the solar cell in such a way that it is interposed between the electric terminal and the solar cell for avoiding the short current and the water penetration. In this way, this package in accordance with the invention tends to increase the array density of the solar cells on the substrate and to minimize the manufacturing cost.

### BACKGROUND OF THE INVENTION

1. Field of the Invention

The invention relates to a solar cell package type with surface mount technology structure, and more particularly this package type can be applied with surface mount technology (SMT) process to mount on the substrate for increasing the array density.

2. Description of the Related Art

The solar receiver is created by electrically connecting the solar cells (mounted on a substrate) in series or in parallel. As shown in FIG. 1, the solar cell 12 mounted on the substrate 11 is electrically connected in series or in parallel by use of the wire bonding process or the wedge bonding process, thereby creating a solar receiver. However, a bonding line distance is required between the wire 13 bonding pad of the solar cells 12 and the bonding pad on the substrate 11 when the electric connection is done by the wire bonding process or the wedge bonding process. As illustrated in FIG. 2, the bonding line distance takes up much space, thereby reducing the array density of the solar cells on the substrate 11. In this way, a great amount of light energy will be lost. That is, the conversion efficiency of the electric energy of the solar receiver is lowered.

Another conventional solar receiver is shown in FIG. 3. The solar cell 22 is provided with conduction through vias 23. The solar cells 22 mounted on the substrate 21 are electrically connected in series or in parallel directly. The electric connection through vias seems to resolve the above-mentioned problem that the bonding line distance is necessary for the wire bonding process, to enhance the solar receiver density of the whole array. However, this solar receiver type according to FIG. 3 tends to cause another problem of the complicated process and the high cost.

### SUMMARY OF THE INVENTION

The purpose of the invention is to provide a solar cell package type with surface mount technology structure that permits an increased array density of the solar cells mounted on the substrate and ensures a considerable reduction of the manufacturing cost.

In order to achieve the above-mentioned object, the invention includes:

a) a solar cell having a first electric terminal at the bottom thereof and a second electric terminal at the top thereof;

b) at least a connection electric terminal capped at both sides of the solar cell in such a way that the top part of this electric terminal is connected to the second electric terminal; and c) at least an insulation layer capped at both sides and partially placed at the bottom of the solar cell in such a way that it is interposed between the connection electric terminal and the solar cell for avoiding the short current.

Moreover, the insulation layer is made of insulation adhesive material (ex. polymer) or dielectric insulating material (ex. SiO₂, Si₃N₄, or ceramic). In addition, the bottom insulation part of the insulation layer is flushed with the first electric terminal of the solar cell or disposed at the bottom of the first electric terminal. Furthermore, the solar cell includes a monolithic silicon solar cell, a poly-silicon solar cell, an amorphous solar cell, a thin-film solar cell, a compound semiconductor solar cell, or an organic solar cell.

### BRIEF DESCRIPTION OF THE DRAWINGS

The accomplishment of all objects of the invention will become apparent from the following descriptions and its accompanying figures of which:

FIG. 1 is a schematic drawing of a conventional solar receiver made by use of the wire-bonding process;

FIG. 2 is a schematic drawing for illustrating the array density of the solar cells of the conventional solar receiver made by use of the wire-bonding process;

FIG. 3 is a schematic drawing of a conventional solar receiver mounted with a solar cell through vias;

FIG. 4 is a schematic drawing of the package type according to a first embodiment of the invention;

FIG. 5 is a schematic drawing of the package type according to a second embodiment of the invention; and

FIG. 6 is a schematic drawing for illustrating the array density of the solar cells in accordance with the invention.

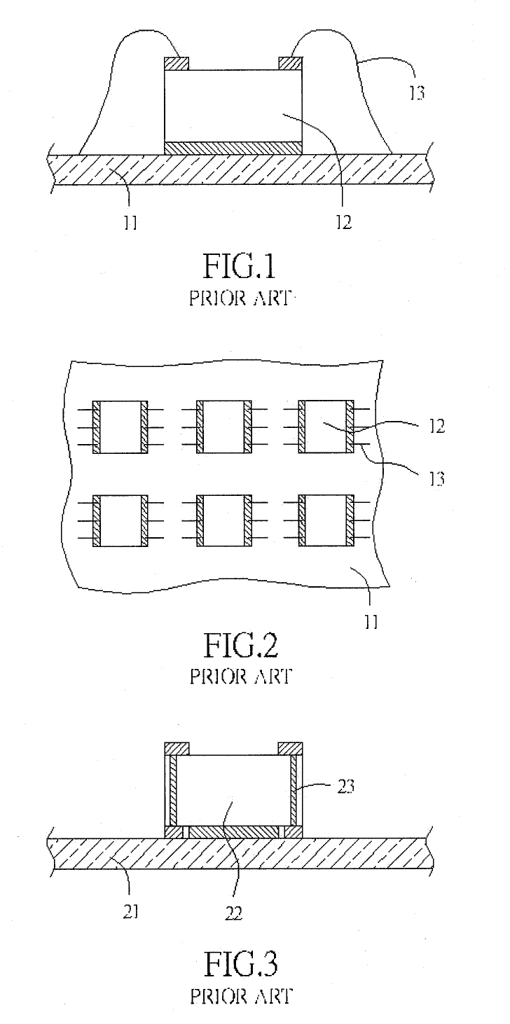

### DETAILED DESCRIPTION OF THE PREFERRED EMBODIMENT

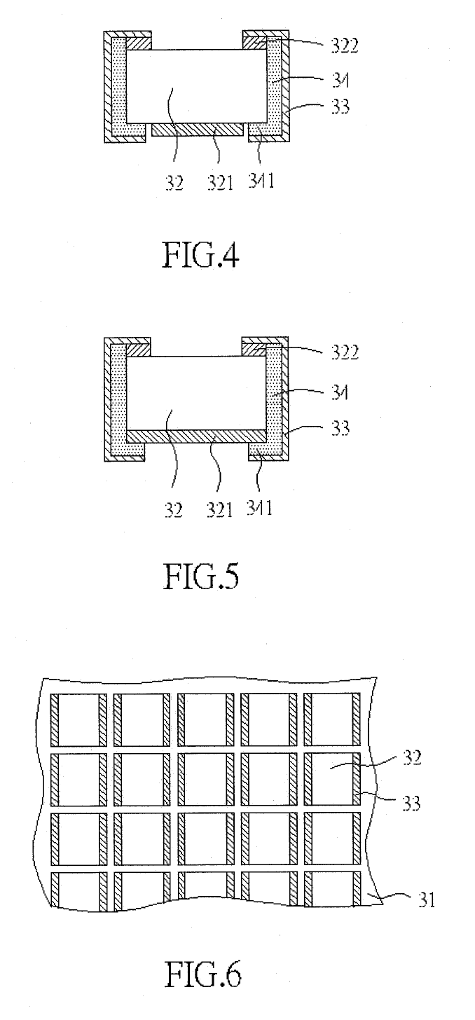

First of all, referring to FIGS. 4 and 5, the package type in accordance with the invention includes a solar cell 32, at least one connection electric terminal 33 (two connection electric terminals 33 illustrated in the drawing), and at least one insulation layer 34 (two insulation layers 34 illustrated in the drawing).

The solar cell 32 includes a first electric terminal 321 at the bottom thereof and a second electric terminal 322 at the top thereof.

The connection electric terminals 33 are capped at both sides of the solar cell 32 in such a way that the top part of this connection electric terminal 33 is connected to the second electric terminal 322.

The insulation layers 34 are capped at both sides and partially placed at the bottom of the solar cell 32 in such a way that they are interposed between the connection electric terminal 33 and the solar cell 32 for avoiding the short current. In fact, the insulation layers 34 are employed to prolong the product life and ensure a long-lasting efficiency.

The solar cell 32 includes a monolithic silicon solar cell, a poly-silicon solar cell, an amorphous solar cell, a thin-film solar cell, a compound semiconductor solar cell, or an organic solar cell, and should not be limited thereto. The bottom insulation part 341 of the insulation layer 34 is flushed with the first electric terminal 321 of the solar cell 32 or disposed at the bottom of the first electric terminal 321. The insulation layer 34 is made of insulation adhesive material (ex. polymer) or dielectric insulating material (ex. SiO₂, Si₃N₄, or ceramic).

Based upon the above-mentioned configuration in accordance with the invention, the surface mount technology (SMT) process can be applied to mount the solar cells package on the substrate 31. These solar cells packages connected in series or in parallel to create a solar receiver, as shown in FIG. 6.

In comparison to the conventional wire-bonding or wedge-bonding process, this package type in accordance with the invention has the following advantages:

1. Unlike the conventional wire-bonding process requiring a certain gap, this package type in accordance with the invention tends to increase the array density of the solar cells 32 on the substrate 31 and to enhance the conversion efficiency of the electric energy of the solar receiver.

2. The surface mount technology (SMT) process has been widely applied. Therefore, the related equipment is relatively cheap and suitable for mass production, thereby reducing the manufacturing cost.

3. The cross-sectional area of the connection electric terminal 33 is greater than that of the wire or the conduction through vias 23. Therefore, the electric and thermal conductivity is superior to the prior art, thereby positively enhancing the conversion efficiency of the electric energy.

Many changes and modifications in the above-described embodiments of the invention can, of course, be carried out without departing from the scope thereof. Accordingly, to promote the progress in science and the useful arts, the invention is disclosed and is intended to be limited only by the scope of the appended claims.

What is claimed is:

1. A solar cell package type with surface mount technology structure, comprising:
a) a solar cell having a first electric terminal at the bottom thereof and a second electric terminal at the top thereof;
b) at least a connection electric terminal capped at both sides of the solar cell in such a way that the top of the electric terminal is connected to the second electric terminal; and
c) at least an insulation layer capped at both sides and partially placed at the bottom of the solar cell in such a way that it is interposed between the connection electric terminal and the solar cell for avoiding the short current.

2. The solar cell package type with surface mount technology structure as recited in claim 1 wherein the insulation layer is made of insulation adhesive material or dielectric insulating material.

3. The solar cell package type with surface mount technology structure as recited in claim 2 wherein the insulation layer is made of polymer, SiO₂, Si₃N₄, or ceramic.

4. The solar cell package type with surface mount technology structure as recited in claim 2 wherein the bottom insulation part of the insulation layer is flushed with the first electric terminal of the solar cell or disposed at the bottom of the first electric terminal.

5. The solar cell package type with surface mount technology structure as recited in claims 4 wherein the solar cell includes a monolithic silicon solar cell, a poly-silicon solar cell, an amorphous solar cell, a thin-film solar cell, a compound semiconductor solar cell, or an organic solar cell.
